(19) United States
(12) Patent Application Publication
(10) Pub. No.: US 2009/0191690 A1
(43) Pub. Date: Jul. 30, 2009

(54) Increasing Die Strength by Etching During or After Dicing

(75) Inventors: Adrian Boyle, County Kildare (IE); David Gillen, Dublin (IE); Kali Dunne, County Roscommon (IE); Eva Fernandez Gomez, Dublin (IE); Richard Toftness, Wayne, NJ (US)

Correspondence Address: SEYFARTH SHAW LLP, 131 S. DEARBORN ST., SUITE 2400, CHICAGO, IL, 60603-5803, US

(73) Assignee: XSIL TECHNOLOGY LIMITED, Dublin (IE)

(21) Appl. No.: 11/666,796

(22) PCT Filed: Nov. 1, 2005
(86) PCT No.: PCT/EP05/11671

§ 371 Date: Apr. 3, 2009

(30) Foreign Application Priority Data
Nov. 1, 2004 (GB) 0424195.6

(51) Int. Cl. H01L 21/78; H01L 21/306

(52) U.S. Cl. 438/462; 156/345.1; 257/E21.599; 257/E21.219

(57) ABSTRACT

A semiconductor wafer having an active layer is mounted on a carrier with the active layer away from the carrier and at least partially diced on the carrier from a major surface of the semiconductor wafer. The at least partially diced semiconductor wafer is etched on the carrier from the said major surface with a spontaneous etchant to remove sufficient semiconductor material from a die produced from the at least partially diced semiconductor wafer to improve flexural bend strength of the die by removing at least some defects caused by dicing.

This invention relates to increasing die strength by etching during or after dicing a semiconductor wafer.

Etching of semiconductors such as silicon with spontaneous etchants is known with a high etch selectivity to a majority of capping, or encapsulation, layers used in the semiconductor industry. By spontaneous etchants will be understood etchants which etch without a need for an external energy source such as electricity, kinetic energy or thermal activation. Such etching is exothermic so that more energy is released during the reaction than is used to break and reform inter-atomic bonds of the reactants. U.S. Pat. No. 6,498,074 discloses a method of dicing a semiconductor wafer part way through with a saw, laser or masked etch from an upper side of the wafer to form grooves at least as deep as an intended thickness of die to be singulated from the wafer. A backside of the wafer, opposed to the upper side, is dry etched, for example with an atmospheric pressure plasma etch of CF₄, past a point at which the grooves are exposed to remove damage and resultant stress from sidewalls and bottom edges and corners of the die, resulting in rounded edges and corners. Preferably a protective layer, such as a polyimide, is used after grooving to hold the die together after singulation and during etching and to protect the circuitry on the top surface of the wafer from etchant passing through the grooves.

However, in order to etch from the backside of the wafer it is necessary to remount the wafer, in, for example, a vortex non-contact chuck, after grooving the upper surface, in order to etch the wafer from an opposite side from that from which the wafer is grooved.

It is an object of the present invention at least to ameliorate the aforesaid shortcoming in the prior art.

According to a first aspect of the present invention there is provided a method of dicing a semiconductor wafer having an active layer comprising the steps of: mounting the semiconductor wafer on a carrier with the active layer away from the carrier; at least partially dicing the semiconductor wafer on the carrier from a major surface of the semiconductor wafer to form an at least partially diced semiconductor wafer; and etching the at least partially diced semiconductor wafer on the carrier from the said major surface with a spontaneous etchant to remove sufficient semiconductor material from a die produced from the at least partially diced semiconductor wafer to improve flexural bend strength of the die.

Conveniently, the step of at least partially dicing the semiconductor wafer comprises dicing the semiconductor wafer completely through the semiconductor wafer; and the step of etching the semiconductor wafer comprises etching sidewalls of the die, remaining portions of the die being masked from the spontaneous etchant by portions of the active layer on the die.

Alternatively, the step of at least partially dicing the semiconductor wafer comprises partially dicing the semiconductor wafer along dicing lanes to leave portions of semiconductor material bridging the dicing lanes; and the step of etching the semiconductor wafer comprises etching sidewalls of the dicing lanes and etching away the portions of semiconductor material bridging the dicing lanes to singulate the die.

Advantageously, the semiconductor wafer is a silicon wafer.

Conveniently, the step of etching with a spontaneous etchant comprises etching with xenon difluoride.

Preferably, the step of etching with a spontaneous etchant comprises providing an etching chamber and etching the semiconductor wafer within the etching chamber.

Advantageously, the step of etching with a spontaneous etchant within the etching chamber comprises cyclically supplying the chamber with spontaneous etchant and purging the etching chamber of spontaneous etchant for a plurality of cycles.

According to a second aspect of the invention, there is provided a dicing apparatus for dicing a semiconductor wafer having an active layer comprising: carrier means on which the semiconductor wafer is mountable with the active layer away from the carrier; laser or mechanical sawing means arranged for at least partially dicing the semiconductor wafer on the carrier from a major surface of the semiconductor wafer to form an at least partially diced semiconductor wafer; and etching means arranged for etching the at least partially diced semiconductor wafer on the carrier from the said major surface with a spontaneous etchant to remove sufficient semiconductor material from a die produced from the at least partially diced semiconductor wafer to improve flexural bend strength of the die.

Conveniently, the dicing apparatus is arranged for dicing a silicon wafer.

Advantageously, the etching means is arranged to etch with xenon difluoride.

Preferably, the dicing apparatus further comprises an etching chamber arranged for etching the semiconductor wafer mounted on the carrier means within the etching chamber.

Preferably, the etching chamber is arranged for cyclically supplying the chamber with spontaneous etchant and purging the etching chamber of spontaneous etchant for a plurality of cycles.

The invention will now be described, by way of example, with reference to the accompanying drawings in which:

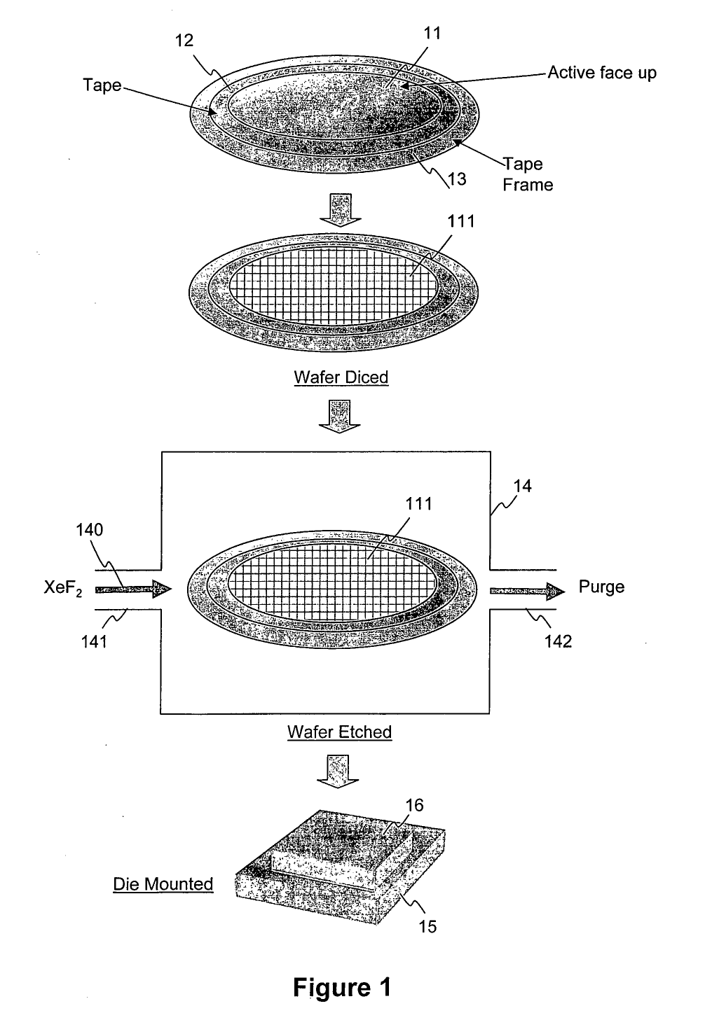

FIG. 1 is a schematic flow diagram of a first embodiment of the invention comprising active side up dicing followed by spontaneous etching;

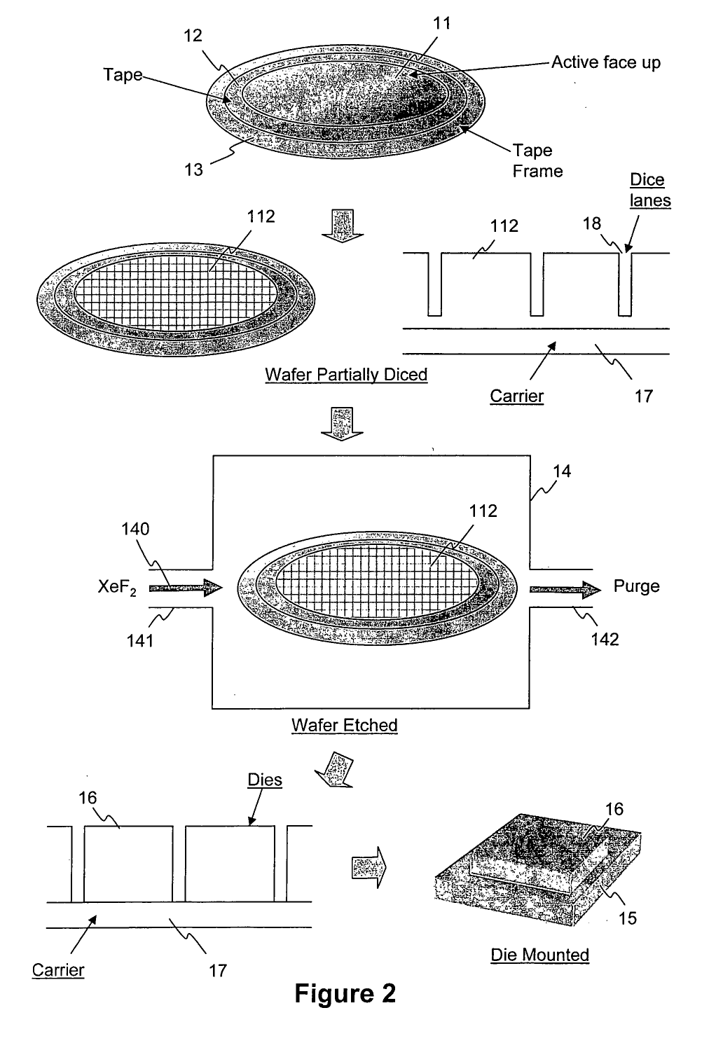

FIG. 2 is a schematic flow diagram of a second embodiment of the invention comprising active face up partial dicing followed by die release by spontaneous etching;

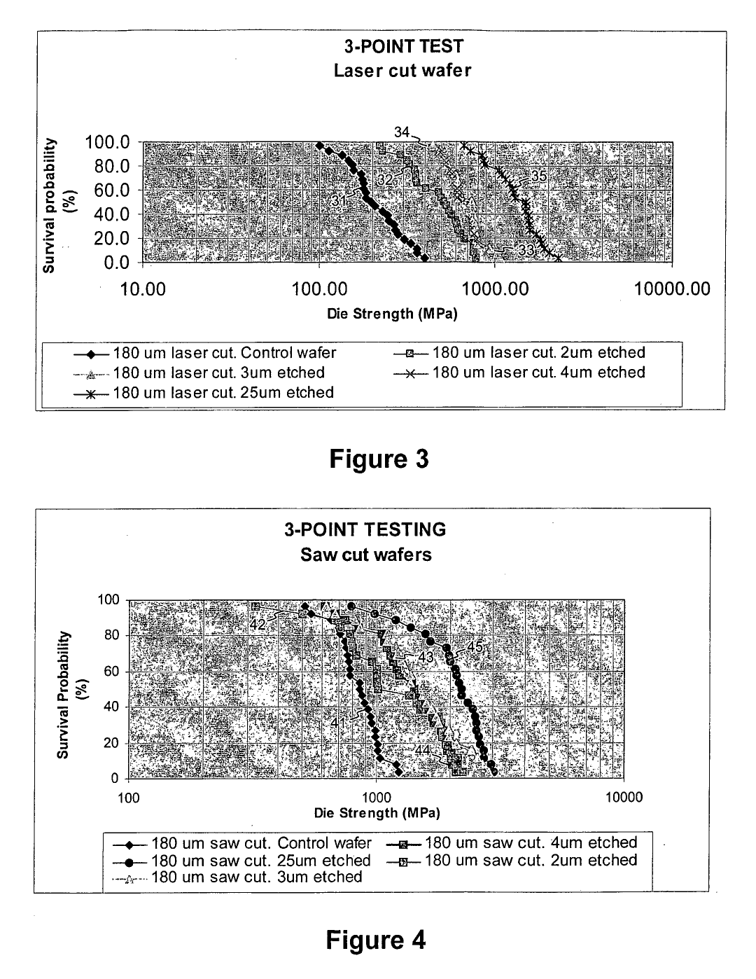

FIG. 3 is a graph of survival probability as ordinates versus die strength as abscissa of a laser-cut control wafer and wafers etched to various extents according to the invention as measured by a 3-point test;

FIG. 4 is a graph of survival probability as ordinates versus die strength as abscissa of a saw-cut control wafer and wafers etched to various extents according to the invention as measured by a 3-point test;

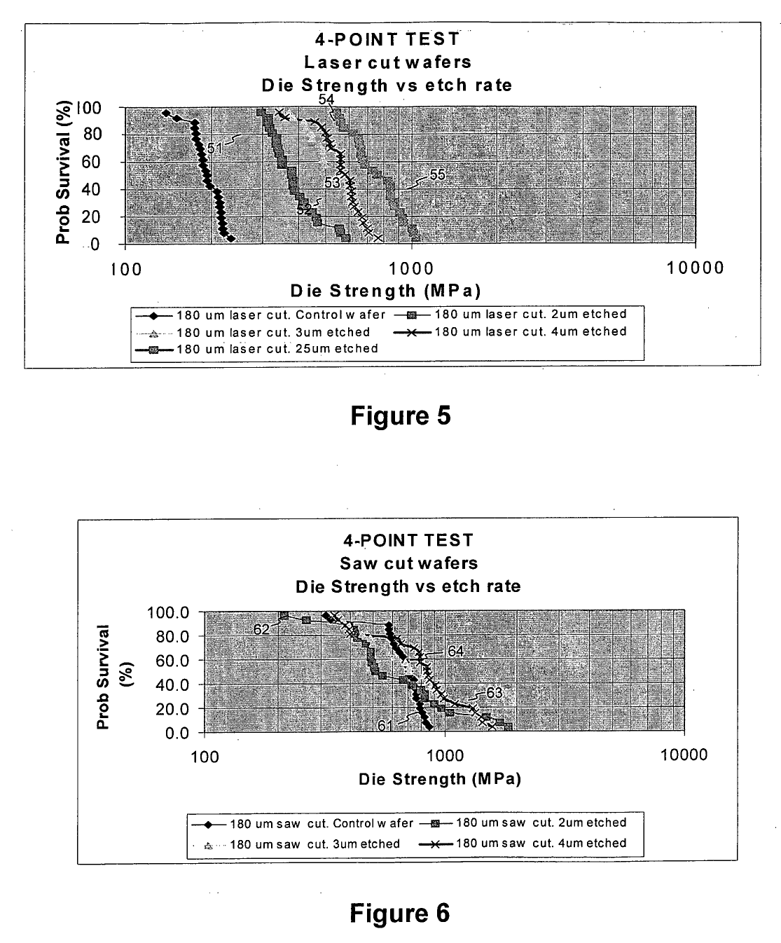

FIG. 5 is a graph of survival probability as ordinates versus die strength as abscissa of a laser-cut control wafer and wafers etched to various extents according to the invention as measured by a 4-point test;

FIG. 6 is a graph of survival probability as ordinates versus die strength as abscissa of a saw-cut control wafer and wafers etched to various extents according to the invention as measured by a 4-point test;

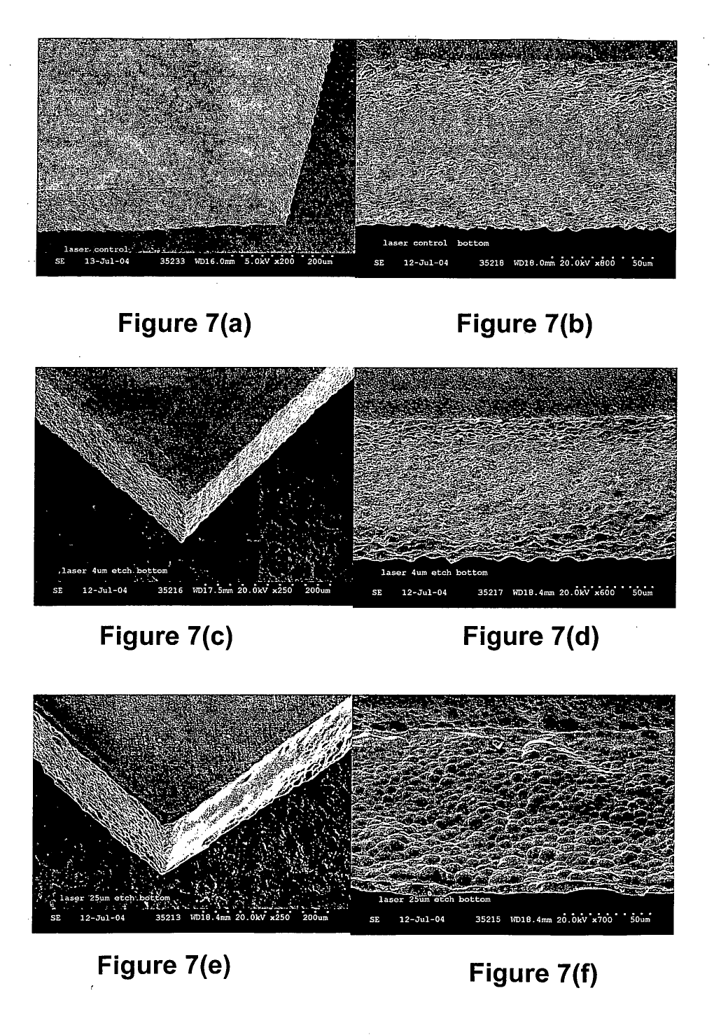

FIG. 7 shows micrographs of sidewalls of a laser-cut control wafer and of laser-cut wafers etched to various extents according to the invention; and

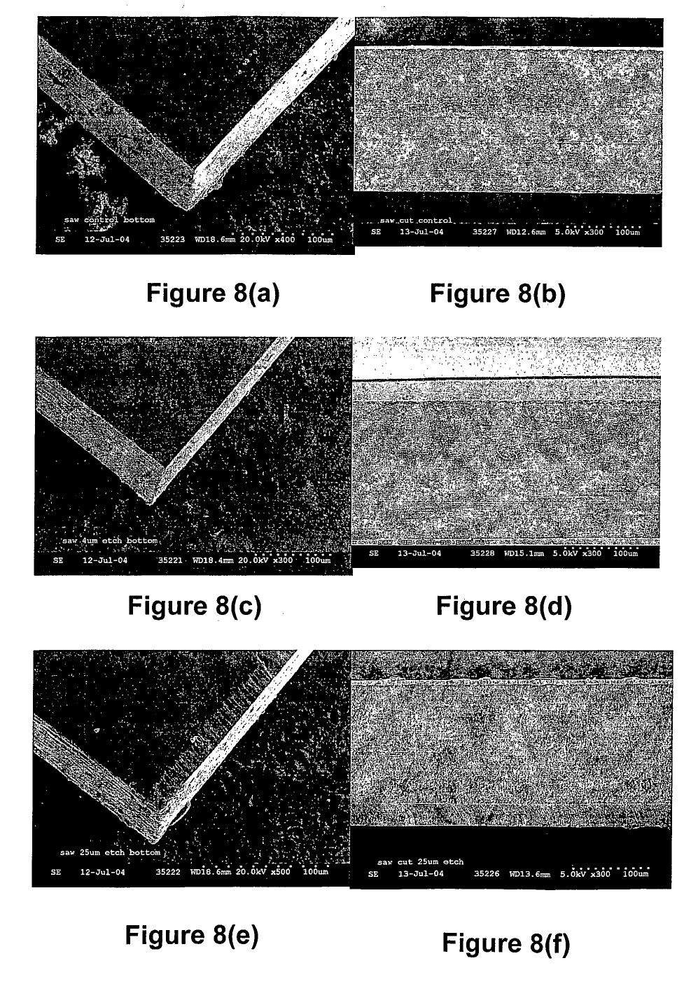

FIG. 8 is of micrographs of sidewalls of a saw-cut control wafer and of saw-cut wafers etched to various extents according to the invention.

### In the Figures like reference numerals denote like parts.

Referring to FIGS. 1 and 2, a silicon wafer 11 on a standard dicing tape 12 and tape frame 13 is mounted on a carrier, not shown. The wafer is diced using a laser or a mechanical saw on the carrier to produce a diced wafer 111. The laser may be a diode-pumped solid-state laser, a mode-locked laser or any other laser suitable for machining the semiconductor and other materials of the wafer. Suitable laser wavelengths may be selected from infrared to ultraviolet wavelengths.

The diced wafer 111 is placed on the carrier in a chamber 14, the chamber having an inlet port 141 and an outlet port 142. Cycles of xenon difluoride (XeF₂), or any other spontaneous etchant of silicon, are input through the inlet port 141 and purged through the outlet port 142 for a predetermined number of cycles each of a predetermined duration. Alternatively, the etching may be carried out as a continuous process, but this has been found to be less efficient in terms of etch rate and etchant usage. The dies are then released from the tape 12 and mounted onto a die pad 15 or another die to form a mounted die 16.

Referring to FIG. 1, in a first embodiment of the invention, a wafer 11, with an active layer uppermost, is diced followed by spontaneous etching. The wafer 11 is mounted active face up on a wafer carrier on a tape 12 and a tape frame 13, that is, with the active layer away from the carrier. The wafer is diced with a mechanical dicing saw or a laser dicing saw on the carrier to form an active side up, diced wafer 111. The diced wafer 111 is placed face up in an etching chamber 14 and a spontaneous etchant 140 of silicon is input into the chamber 14 through the inlet port 141 to come in contact with the diced wafer 111 for a pre-defined period. The etchant can be, but is not limited to, XeF₂ and can be either a gas or liquid. The diced wafer 111 is held in place in the chamber 14 by the wafer carrier, not shown, which can be made of any flexible or inflexible material that holds the wafer in place either through the use of an adhesive layer or by mechanical means such as physical, electrical or vacuum clamping. The wafer carrier can be opaque or optically transparent. After etching, singulated etched dies 16 are removed from the carrier and mounted onto a die pad 15 or another die. In this embodiment, the active layer acts as a mask to the spontaneous etchant and only the sidewalls of the dies are etched to remove a layer of silicon. The etching of the sidewall changes the physical nature of the sidewall thereby increasing the average die strength, as measured to destruction with a three-point or four-point test.

Referring to FIG. 2, in a second embodiment of the invention, a wafer 11, with an active layer uppermost is mounted active side up on a tape 12 and tape frame 13 on a wafer carrier 17. The wafer carrier 17 can be made of any optically transparent flexible or inflexible material that is suitable for holding the wafer in place either through the use of an adhesive layer or by mechanical means such as mechanical, electrical or vacuum clamping. The wafer 11 is partially diced through along dice lanes 18 with a mechanical dicing saw or a laser dicing saw to form a partially diced wafer 112. The partially diced wafer 112 is placed face up, on the carrier 17, in an etching chamber 14 to come into contact with a spontaneous etchant 140 of silicon until the etchant 140 has etched away a remaining portion of silicon in the dice lanes. The etchant can be, but is not limited to, XeF₂ and can be either a gas or liquid. As well as by a change in physical nature of the sidewall, die strength is also enhanced because the dies are diced substantially simultaneously, avoiding any stress build up which may occur in conventionally diced wafers.

The process of the invention provides the advantages over other etch processes, such as chemical or plasma etching, of being a fully integrated, dry, controllable, gas process, so that no specialist wet chemical handling is required, and clean, safe and user-friendly materials are used in a closed handling system that lends itself well to automation. Moreover, since spontaneous etching may be carried out in parallel with dicing, cycle time is of the order of dicing process time, so that throughput is not restricted. Furthermore, the invention uses a tape-compatible etch process which is also compatible with future wafer mounts, such as glass. In addition, no plasma is used, as in the prior art, which might otherwise induce electrical damage on sensitive electrical devices. Finally, the invention provides an inexpensive process which, used with laser dicing, provides a lower cost dicing process than conventional dicing processes.

### EXAMPLE

Ten 125 mm diameter 180 μm thick silicon wafers were coated with standard photoresist. The wafers were split into two groups as shown in Table 1 with five wafers undergoing laser dicing and five wafers undergoing dicing by mechanical saw.

TABLE 1
Wafer description

| Wafer | Dicing | Etch depth |
|---|---|---|
| number | Process | (μm) |
| 1 | Laser | Not etched |
| 2 | | 2 |
| 3 | | 3 |
| 4 | | 4 |
| 5 | | 25 |
| 6 | Saw | Not etched |
| 7 | | 2 |
| 8 | | 3 |
| 9 | | 4 |
| 10 | | 25 |

After dicing the wafers were placed in a chamber and etched with XeF₂ for a predetermined period of time. After this period the chamber was evacuated and purged. This etch, evacuate and purge cycle was repeated for a set number of times to remove a predetermined thickness of silicon. The numbers of cycles used are given in Table 2.

TABLE 2
Etching parameters

| Etch depth | Number of | Time per |
|---|---|---|
| (μm) | cycles | cycle (sec) |
| Not etched | — | — |
| 2 μm | 8 | 10 |
| 3 μm | 12 | 10 |
| 4 μm | 16 | 10 |
| 25 μm | 100 | 10 |

After the wafers had been etched, the die strength of each wafer was measured using 3-point and 4-point flexural bend strength testing.

The results for 3-point die strength testing are listed in Table 3 for laser-cut wafers and Table 4 for saw-cut. wafers. Corresponding graphs comparing the survival probability for the control wafer with the four different etch depths used are shown in FIG. 3 for laser-cut wafers, in which line 31 relates to an un-etched wafer, line 32 an etch depth of 2 μm, line 33 an etch depth of 3 μm, line 34 an etch depth of 4 μm and line 35 an etch depth of 25 μm and in FIG. 4 for saw-cut wafers in which line 41 relates to an un-etched wafer, line 42 an etch depth of 2 μm, line 43 an etch depth of 3 μm, line 44 an etch depth of 4 μm and line 45 an etch depth of 25 μm. It can be seen that for both laser-cut and saw-cut wafers the flexural strength as measured by a 3-point test generally increases with etch depth.

TABLE 3
Laser cut wafers. 3-Point Die Strength Test
Normalised Die Strength (MPa) for Xise laser diced wafers

| | Control | 2 μm | 3 μm | 4 μm | 25 μm |
|---|---|---|---|---|---|
| | wafer | etched | etched | etched | etched |
| Average (MPa) | 223 | 506 | 697 | 658 | 1381 |
| Std Dev (MPa) | 83 | 178 | 162 | 131 | 417 |
| Max (MPa) | 404 | 799 | 1077 | 920 | 2279 |
| Min (MPa) | 100 | 221 | 446 | 403 | 663 |
| Range (MPa) | 304 | 578 | 632 | 518 | 1616 |
| Coeff. of variance | 0.37 | 0.35 | 0.23 | 0.20 | 0.30 |

TABLE 4
Saw cut wafers. 3-Point Die Strength Test
Normalised Die Strength (MPa) for mechanical saw cut wafers

| | Control | 2 μm | 3 μm | 4 μm | 25 μm |
|---|---|---|---|---|---|
| | wafer | etched | etched | etched | etched |
| Average (MPa) | 861 | 1308 | 1585 | 1427 | 2148 |
| Std Dev (MPa) | 181 | 593 | 623 | 457 | 601 |
| Max (MPa) | 1245 | 2250 | 2894 | 2119 | 3035 |
| Min (MPa) | 512 | 321 | 622 | 617 | 790 |
| Range (MPa) | 733 | 1929 | 2272 | 1502 | 2246 |
| Coeff. of variance | 0.21 | 0.45 | 0.39 | 0.32 | 0.28 |

The results for 4-point die strength testing are listed in Tables 5 and 6. Corresponding graphs comparing the survival probability for the control wafer and the four different etch tests are shown in FIG. 5 for laser-cut wafers, in which line 51 relates to an un-etched wafer, line 52 an etch depth of 2 μm, line 53 an etch depth of 3 μm, line 54 an etch depth of 4 μm and line 55 an etch depth of 25 μm and in FIG. 6 for saw-cut wafers in which line 61 relates to an un-etched wafer, line 62 an etch depth of 2 μm, line 63 an etch depth of 3 μm, and line 64 an etch depth of 4 μm. It can be seen that for both laser-cut and saw-cut wafers the flexural strength as measured by a 4-point test generally increases with etch depth.

TABLE 5
Laser cut wafers. 4-Point Die Strength Test
Normalised Die Strength (MPa) for Xise laser diced wafers

| | Control | 2 μm | 3 μm | 4 μm | 25 μm |
|---|---|---|---|---|---|
| | wafer | etched | etched | etched | etched |
| Average (MPa) | 194 | 394 | 551 | 574 | 770 |
| Std Dev (MPa) | 23 | 81 | 109 | 101 | 155 |
| Max (MPa) | 234 | 588 | 743 | 762 | 1043 |
| Min (MPa) | 139 | 296 | 370 | 342 | 543 |
| Range (MPa) | 95 | 291 | 373 | 419 | 500 |
| Coeff of variance | 0.12 | 0.20 | 0.20 | 0.18 | 0.20 |

TABLE 6
Saw cut wafers. 4-Point Die Strength Test
Normalised Die Strength (MPa) for mechanical saw diced wafers

| | Control | 2 μm | 3 μm | 4 μm | 25 μm |
|---|---|---|---|---|---|
| | wafer | etched | etched | etched | etched |
| Average (MPa) | 680 | 716 | 843 | 868 | — |
| Std Dev (MPa) | 137 | 425 | 399 | 357 | — |
| Max (MPa) | 863 | 1851 | 1608 | 1583 | — |
| Min (MPa) | 316 | 213 | 365 | 344 | — |
| Range (MPa) | 547 | 1638 | 1244 | 1240 | — |
| Coeff of variance | 0.20 | 0.59 | 0.47 | 0.41 | — |

SEM images of the laser-cut and saw-cut wafers are shown in FIGS. 7 and 8 respectively. FIG. 7(a) shows a laser-cut un-etched die corner at ×200 magnification, FIG. 7(b) shows a laser-cut un-etched sidewall at ×800 magnification, FIG. 7(c) shows a laser-cut die corner etched 4 μm at ×250 magnification, FIG. 7(d) shows a laser-cut sidewall etched 4 μm at ×600 magnification, FIG. 7(e) shows a laser-cut die corner etched 25 μm at ×250 magnification, FIG. 7(f) shows a laser-cut sidewall etched 25 μm at ×700 magnification. FIG. 8(a) shows a saw-cut un-etched die corner at ×400 magnification, FIG. 8(b) shows a saw-cut un-etched sidewall at ×300 magnification, FIG. 8(c) shows a saw-cut die corner etched 4 μm at ×300 magnification, FIG. 8(d) shows a saw-cut sidewall with no resist etched 4 μm at ×300 magnification, FIG. 8(e) shows a saw-cut die corner etched 25 μm at ×500 magnification, FIG. 8(f) shows a saw-cut sidewall etched 25 μm at ×300 magnification.

For both the 3-point and 4-point tests, it can be seen that for both saw-cut and laser-cut die, on average the etched dies had higher flexural strength than the un-etched dies and the flexural strength increases with depth of etch in the etch range 2 μm to 25 μm.

Although the invention has been described in relation to silicon and xenon difluoride, it will be understood that any suitable liquid or gaseous spontaneous etchant such as a halide or hydrogen compound, for example F₂, Cl₂, HCl or HBr may be used with silicon or another semiconductor.

1. A method of dicing a semiconductor wafer having an active layer comprising the steps of:
a. mounting the semiconductor wafer on a carrier with the active layer away from the carrier;
b. at least partially dicing the semiconductor wafer on the carrier from a major surface of the semiconductor wafer to form an at least partially diced semiconductor wafer; and
c. etching the at least partially diced semiconductor wafer on the carrier from the said major surface with a spontaneous etchant to remove sufficient semiconductor material from a die produced from the at least partially diced semiconductor wafer to improve flexural bend strength of the die.

2. A method as claimed in claim 1, wherein the step of at least partially dicing the semiconductor wafer comprises dicing the semiconductor wafer completely through the semiconductor wafer; and the step of etching the semiconductor wafer comprises etching sidewalls of the die, remaining portions of the die being masked from the spontaneous etchant by portions of the active layer on the die.

3. A method as claimed in claim 1, wherein the step of at least partially dicing the semiconductor wafer comprises partially dicing the semiconductor wafer along dicing lanes to leave portions of semiconductor material bridging the dicing lanes; and the step of etching the semiconductor wafer comprises etching sidewalls of the dicing lanes and etching away the portions of semiconductor material bridging the dicing lanes to singulate the die.

4. A method as claimed in claim 1, wherein the semiconductor wafer is a silicon wafer.

5. A method as claimed in claim 1, wherein the step of etching with a spontaneous etchant comprises etching with xenon difluoride.

6. A method as claimed in claim 1, wherein the step of etching with a spontaneous etchant comprises providing an etching chamber and etching the semiconductor wafer within the etching chamber.

7. A method as claimed in claim 6, wherein the step of etching with a spontaneous etchant within the etching chamber comprises cyclically supplying the chamber with spontaneous etchant and purging the etching chamber of spontaneous etchant for a plurality of cycles.

8. A dicing apparatus for dicing a semiconductor wafer having an active layer comprising:
a. carrier means on which the semiconductor wafer is mountable with the active layer away from the carrier;
b. laser or mechanical sawing means arranged for at least partially dicing the semiconductor wafer on the carrier from a major surface of the semiconductor wafer to form an at least partially diced semiconductor wafer; and
c. etching means arranged to etch the at least partially diced semiconductor wafer on the carrier from the said major surface with a spontaneous etchant to remove sufficient semiconductor material from a die produced from the at least partially diced semiconductor wafer to improve flexural bend strength of the die.

9. A dicing apparatus as claimed in claim 8, wherein the dicing apparatus is arranged to dice a silicon wafer.

10. A dicing apparatus as claimed in claim 8, wherein the etching means is arranged to etch with xenon difluoride.

11. A dicing apparatus as claimed in claim 8, wherein the dicing apparatus further comprises an etching chamber arranged for etching the semiconductor wafer mounted on the carrier means within the etching chamber.

12. A dicing apparatus as claimed in claim 8, wherein the etching chamber is arranged cyclically to supply the chamber with spontaneous etchant and to purge the etching chamber of spontaneous etchant for a plurality of cycles.
